(19) United States
(12) Patent Application Publication
(10) Pub. No.: US 2024/0258341 A1
(43) Pub. Date: Aug. 1, 2024

(54) DRIVING BACKPLANE AND DISPLAY PANEL

(71) Applicant: Shenzhen China Star Optoelectronics Semiconductor Display Technology Co., Ltd., Shenzhen (CN)

(72) Inventors: Zhuhui LI, Shenzhen (CN); Yanfen LI, Shenzhen (CN)

(21) Appl. No.: 18/542,704

(22) Filed: Dec. 17, 2023

(30) Foreign Application Priority Data
Jan. 31, 2023 (CN) 202310093535.7

(51) Int. Cl. H01L 27/12; H01L 25/16

(52) U.S. Cl. CPC H01L 27/1248; H01L 25/167; H01L 27/1244

(57) ABSTRACT

A driving backplane and a display panel are provided. The driving backplane includes a substrate, a driving circuit layer, a protective layer, and pads. The driving circuit layer is disposed on a side of the substrate, and its top forms a first height with a bottom of the substrate. The protective layer is disposed on a side of the driving circuit layer facing away from the substrate, and includes first protective layer structures. Each first protective layer structure corresponds to each pad area. The pads are formed on sides of the first protective layer structures facing away from the driving circuit layer, each pad is connected to the driving circuit layer through a via hole in each first protective layer structure, and a top of one first protective layer structure forms a second height with the bottom of the substrate, and the second height is greater than the first height.

### CROSS-REFERENCE TO RELATED APPLICATION

This application claims priority to Chinese Patent Application No. 202310093535.7, filed on Jan. 31, 2023, the disclosure of which is incorporated herein by reference in its entirety.

### TECHNICAL FIELD

The present disclosure relates to the field of display technologies, and in particular, to a driving backplane and a display panel.

### BACKGROUND

Compared with current mainstream display technologies such as liquid crystal display (LCD) and organic light-emitting diode (OLED), micro light-emitting diode (Micro LED) has intergenerational advantages in brightness, resolution, energy consumption, service life, response speed and thermal stability, and is an internationally recognized future display technology.

However, Micro LED technology is still far from mass production, and mass transfer is a first problem to be solved urgently. Transferring Micro-LED chips to a driving backplane by using a stamp mass transfer technology needs to go through the following processes: firstly, bonding an anisotropic conductive film (ACF) on the driving backplane for connecting the Micro-LED chips with the driving backplane, then stamping and aligning with the driving backplane, and transferring stamped Micro-LED chips to the driving backplane, finally, by pressing and heating, fixing the Micro-LED chips on the driving backplane through the ACF to complete the mass transfer. In an ACF bonding process of the stamp mass transfer technology, a roller exerts a certain pressure on the driving backplane, which will crush circuits on the driving backplane, and at the same time, the circuits on the driving backplane are crushed in the process of stamping and pressing, which will lead to the short circuit phenomenon of the driving backplane and seriously affect the product yield.

Therefore, the driving backplane in the related art has the technical problem that circuits are easy to be crushed, resulting in the short circuit phenomenon, thus affecting the product yield, which needs to be improved.

### SUMMARY

Embodiments of the present disclosure provide a driving backplane and a display panel, which are used for solving the technical problem that the circuits of the driving backplane in the related art are easy to be crushed, resulting in the short circuit phenomenon, thus affecting the product yield.

The present disclosure provides a driving backplane including multiple pad areas and multiple non-pad areas, and the driving backplane includes:
a substrate;
a driving circuit layer, disposed on a side of the substrate; and a top of the driving circuit layer forming a first height with a bottom of the substrate;
a protective layer, disposed on a side of the driving circuit layer facing away from the substrate; the protective layer including multiple first protective layer structures, and each first protective layer structure is disposed corresponding to each pad area; and
multiple pads, formed on sides of the first protective layer structures facing away from the driving circuit layer; each pad is connected with the driving circuit layer through a via hole in each first protective layer structure;
a top of at least one first protective layer structure forming a second height with the bottom of the substrate, and the second height being greater than the first height.

In the driving backplane of the present disclosure, the driving circuit layer includes multiple signal lines, and orthogonal projections of at least two signal lines on the substrate intersect to form an overlapping area; and an orthogonal projection of the first protective layer structure on the substrate does not overlap with the overlapping area.

In the driving backplane of the present disclosure, the protective layer includes at least one second protective layer structure, disposed around the pad area; and a top of the second protective layer structure forms a third height with the bottom of the substrate, and the third height is greater than the first height and less than the second height.

In the driving backplane of the present disclosure, the at least one second protective layer structure is a plurality of second protective layer structures, and the protective layer structures form a grid shape.

In the driving backplane of the present disclosure, the driving backplane further includes a display area and a gate on array (GOA) circuit area, the GOA circuit area is disposed on at least one side of the display area, the driving circuit layer includes multiple GOA driving units, the GOA circuit area includes a first GOA circuit area and a second GOA circuit area, and the GOA driving units are disposed in the first GOA circuit area; the protective layer includes at least one third protective layer structure disposed in the second GOA circuit area; and a top of the third protective layer structure forms a fourth height with the bottom of the substrate, and the fourth height is greater than the first height and less than the third height.

In the driving backplane of the present disclosure, the third protective layer structure is disposed around the GOA driving units.

In the driving backplane of the present disclosure, the driving backplane further includes a fan-out area, and the driving circuit layer further includes a fan-out line disposed in the fan-out area; the protective layer includes a fourth protective layer structure disposed in the fan-out area; and a top of the fourth protective layer structure forms a fifth height with the bottom of the substrate, and the fifth height is greater than the first height and less than the third height.

In the driving backplane of the present disclosure, the fourth protective layer structure covers the fan-out area throughout its entire layer.

In the driving backplane of the present disclosure, a material of the protective layer is an organic photoresist.

The present disclosure further provides a display panel, including a driving backplane and a light source, wherein the driving backplane includes:
a substrate;
a driving circuit layer, disposed on a side of the substrate; wherein a top of the driving circuit layer forms a first height with a bottom of the substrate;
a protective layer, disposed on a side of the driving circuit layer facing away from the substrate; wherein the protective layer includes a plurality of first protective layer structures, and each of the first protective layer structures is disposed corresponding to each of the plurality of pad areas; and
a plurality of pads, formed on sides of the first protective layer structures facing away from the driving circuit layer; wherein each of the plurality of pads is connected with the driving circuit layer through a via hole in each of the first protective layer structures;
wherein a top of at least one of the first protective layer structures forms a second height with the bottom of the substrate, and the second height is greater than the first height.

In the display panel of the present disclosure, the driving circuit layer include a plurality of signal lines, and orthogonal projections of at least two of the signal lines on the substrate intersect to form an overlapping area; and an orthogonal projection of each of the first protective layer structures on the substrate does not overlap with the overlapping area.

In the display panel of the present disclosure, the protective layer includes at least one second protective layer structure, disposed around the pad area; and a top of the second protective layer structure forms a third height with the bottom of the substrate, and the third height is greater than the first height and less than the second height.

In the display panel of the present disclosure, the at least one second protective layer structure is a plurality of second protective layer structures, and the protective layer structures form a grid shape.

In the display panel of the present disclosure, the driving backplane further includes a display area and a gate on array (GOA) circuit area, the GOA circuit area is disposed on at least one side of the display area, the driving circuit layer includes a plurality of GOA driving units, the GOA circuit area includes a first GOA circuit area and a second GOA circuit area, and the GOA driving units are disposed in the first GOA circuit area; the protective layer includes at least one third protective layer structure disposed in the second GOA circuit area; and a top of the third protective layer structure forms a fourth height with the bottom of the substrate, and the fourth height is greater than the first height and less than the third height.

In the display panel of the present disclosure, the third protective layer structure is disposed around the GOA driving units.

In the display panel of the present disclosure, the driving backplane further includes a fan-out area, and the driving circuit layer further includes a fan-out line disposed in the fan-out area; the protective layer includes a fourth protective layer structure disposed in the fan-out area; and a top of the fourth protective layer structure forms a fifth height with the bottom of the substrate, and the fifth height is greater than the first height and less than the third height.

In the display panel of the present disclosure, the fourth protective layer structure covers the fan-out area throughout its entire layer.

In the display panel of the present disclosure, a material of the protective layer is an organic photoresist.

The present disclosure also provides a driving backplane, including: a plurality of pad areas and a plurality of non-pad areas; wherein the driving backplane includes:
a substrate;
a driving circuit layer, disposed on a side of the substrate; wherein a top of the driving circuit layer forms a first height with a bottom of the substrate;
a protective layer, disposed on a side of the driving circuit layer facing away from the substrate; wherein the protective layer includes a plurality of first protective layer structures, and each of the first protective layer structures is disposed corresponding to each of the plurality of pad areas; and
a plurality of pads, formed on sides of the first protective layer structures facing away from the driving circuit layer; wherein each of the plurality of pads is connected with the driving circuit layer through a via hole in each of the first protective layer structures;
wherein a top of at least one of the first protective layer structures forms a second height with the bottom of the substrate, and the second height is greater than the first height;
wherein the driving circuit layer include a plurality of signal lines, and orthogonal projections of at least two of the signal lines on the substrate intersect to form an overlapping area; and an orthogonal projection of each of the first protective layer structures on the substrate does not overlap with the overlapping area;
wherein the protective layer includes at least one second protective layer structure, disposed around the pad area; and a top of the second protective layer structure forms a third height with the bottom of the substrate, and the third height is greater than the first height and less than the second height.

In the driving backplane of the present disclosure, the at least one second protective layer structure is a plurality of second protective layer structures, and the protective layer structures form a grid shape.

Beneficial effects: the present disclosure provides a driving backplane and a display panel. The driving backplane includes multiple pad areas and multiple non-pad areas, the driving backplane includes a substrate, a driving circuit layer, a protective layer and multiple pads, the driving circuit layer is disposed on a side of the substrate, a top of the driving circuit layer form a first height with a bottom of the substrate, the protective layer is disposed on a side of the driving circuit layer facing away from the substrate, the protective layer includes multiple first protective layer structures, the first protective layer structures are respectively arranged corresponding to the pad areas, the pads are formed on sides of the first protective layer structures facing away from the driving circuit layer, each pad is connected with the driving circuit layer through a via hole in each first protective layer structure, a top of at least one first protective layer structure forms a second height with the bottom of the substrate, and the second height is greater than the first height. The present disclosure optimizes the graphic design of the protective layer to achieve the effect of adjusting the thickness of film layers, the transfer yield is guaranteed by ensuring the highest terrain at the first protective layer structure, and the panel circuits are not pressed during the ACF bonding process and the stamping and pressurizing process, thereby avoiding the occurrence of backplate short circuits and greatly improving the product yield.

### BRIEF DESCRIPTION OF THE DRAWINGS

The technical solutions and other beneficial effects of the present disclosure will be apparent by describing the specific embodiments of the present disclosure in detail with the attached drawings.

FIG. 1 illustrates a structural schematic view of film layers of a driving backplane according to an embodiment of the present disclosure.

FIG. 2 illustrates a schematic view of a cross section of the driving backplane according to an embodiment of the present disclosure.

FIG. 3 illustrates a top view of the driving backplane according to an embodiment of the present disclosure.

FIG. 4 illustrates a schematic layout view of second protective layer structures according to an embodiment of the present disclosure.

### DETAILED DESCRIPTION

The technical solutions in the embodiments of the present disclosure will be clearly and completely described below with reference to the accompanying drawings. Apparently, the described embodiments are merely some of the embodiments of the present disclosure, not all of embodiments of the present disclosure. Based on the described embodiments in the present disclosure, all other embodiments obtained by those skilled in the art without making creative efforts belong to the scope of protection of the present disclosure.

In the description of the present disclosure, it should be understood that orientations or positional relationships indicated by terms “center”, “longitudinal”, “transversal”, “length”, “width”, “thickness”, “upper”, “lower”, “front”, “rear”, “left”, “right”, “vertical”, “horizontal”, “top”, “bottom”, “inner”, “outer”, “clockwise”, “anticlockwise”, and the like are based on orientation or positional relationships shown in the attached drawings, and are only for the convenience of describing the present disclosure and simplifying the description, rather than indicating or implying that a device or a component referred to must have a particular orientation, be constructed and operated in a particular orientation, and therefore the terms cannot be understood as a limitation of the present disclosure. In addition, the terms “first” and “second” are only used for descriptive purposes, and cannot be understood as indicating or implying relative importance or implicitly indicating the number of indicated technical features. Thus, the features defined by “first” and “second” may be explicitly or implicitly defined to include one or more of the stated features. In the description of the present disclosure, “multiple” means two or more, unless otherwise specifically defined.

In the description of the present disclosure, it should be noted that unless otherwise specified and limited, the terms “installation”, “connection”, and “connected” should be broadly understood, for example, they can be fixed connection, detachable connection, or integrated connection; they can be mechanical connection, electrical connection, or communication with each other; they can be directly connected or indirectly connected through an intermediate medium; they can be the internal connection between two components or the interaction relationship between two components. For those skilled in the art, the specific meanings of the above terms in the present disclosure can be understood based on specific circumstances.

In the present disclosure, unless otherwise explicitly specified and limited, the expression that the first feature is “above” or “below” the second feature may include the first and second features being in direct contact, or may also include the first and second features not being in direct contact but being in connection via another feature between them. Moreover, a first feature is “on”, “above” and “on top of” a second feature includes that the first feature being directly above and diagonally above the second feature, or simply means that the first feature is at a higher level than the second feature. A first feature is “under”, “below” and “beneath” a second feature includes that the first feature being directly below and diagonally below the second feature, or simply means that the first feature is at a lower level than the second feature.

The following disclosed contents provide many different embodiments or examples to implementing different structures of the present disclosure. In order to simplify the disclosure of the present disclosure, components and arrangements of specific examples are described below. Of course, they are only examples and are not intended to limit the present disclosure. Furthermore, the present disclosure may repeat reference numerals and/or reference letters in different examples, and such repetition being for the purpose of simplicity and clarity, and not being indicative of relationship among various embodiments and/or arrangements discussed. In addition, the present disclosure provides examples of various specific processes and materials, but those skilled in the art can realize the application of other processes and/or the use of other materials.

The embodiments of the present disclosure provide a driving backplane and a display panel which are used for solving the technical problem that the circuits of the driving backplane in the related art are easy to be crushed, resulting in the short circuit phenomenon, thus affecting the product yield.

In the related art, there are three common methods to improve the short circuit of Micro-LED panels. One is to increase a thickness of an insulating layer between circuits, but this method is limited by chemical vapor deposition (CVD) film forming machine and dry etching machine;

another is to increase a film forming temperature between insulating layers, but this method has limited improvement effect because the insulating layers are very thin; still another method is to optimize an ACF and pressure parameters of stamping, and this method has limited improvement effect because the related pressure cannot be too small.

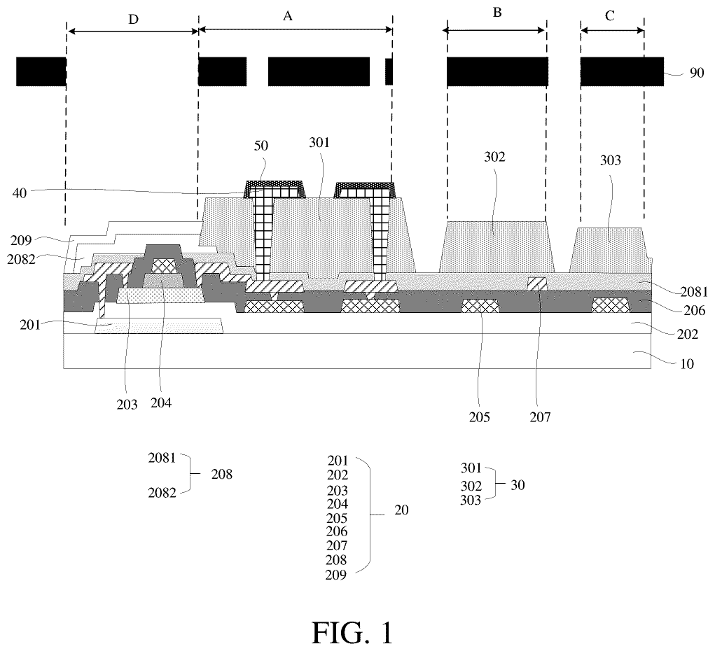

Therefore, an embodiment of the present disclosure provides a driving backplane for improving the short circuit of Micro-LED panels, as shown in FIG. 1, FIG. 1 illustrates a schematic view of film layers of the driving backplane provided by the embodiment of the present disclosure. The driving backplane includes multiple pad areas A and multiple non-pad areas. Specifically, the driving backplane includes:
a substrate 10;
a driving circuit layer 20, disposed on a side of the substrate 10; a top of the driving circuit layer 20 forming a first height h₁ with a bottom of the substrate 10;
a protective layer 30, disposed on a side of the driving circuit layer 20 facing away from the substrate 10, and the protective layer 30 including multiple first protective layer structures 301, each first protective layer structure 301 being arranged corresponding to each pad area A;
multiple pads 40, formed on sides of the first protective layer structures 301 facing away from the driving circuit layer 20, and each pad 40 being connected with the driving circuit layer 20 through a via hole defined in each first protective layer structure 301; and
a top of at least one first protective layer structure 301 forming a second height h₂ with the bottom of the substrate 10, and the second height h₂ is greater than the first height h₁.

Alternatively, the substrate 10 may be a rigid substrate or a flexible substrate. When the substrate 10 is the rigid substrate, it may include a hard substrate such as a glass substrate. When the substrate 10 is the flexible substrate, it may include a polyimide (PI) film, an ultra-thin glass film and another flexible substrate, and a flexible display panel can be made by using the flexible substrate as the substrate 10, so as to realize special properties such as bending and curling of the display panel.

In the driving circuit layer 20, pixel driving circuits for driving sub-pixels to emit light are integrated. The sub-pixels are disposed in an array in the driving backplane, each sub-pixel has the same size and shape, each sub-pixel is driven by the pixel driving circuit. A picture is displayed in a display stage, and in a detection stage, the pixel driving circuit detects a threshold voltage of a transistor, and compensates a data signal according to the detected threshold voltage, so that each sub-pixel can normally emit light.

Specifically, as shown in FIG. 1, in a direction facing away from the substrate 10, the driving circuit layer 20 includes a light shielding layer 201, a buffer layer 202, an active layer 203, a gate insulating layer 204, a first metal layer 205, an interlayer dielectric layer 206, a second metal layer 207, a passivation layer 208 and a black matrix layer 209 which are stacked.

The light shielding layer 201 is disposed on a side of the substrate 10. Preferably, a material of the light shielding layer 201 includes one or more alloys of molybdenum (Mo), aluminum (Al), copper (Cu) and titanium (Ti), and further includes molybdenum/copper laminated layer (Mo/Cu), molybdenum titanium alloy/copper laminated layer (MoTi/Cu) and the like. The buffer layer 202 is disposed on a side of the light shielding layer 201 facing away from the substrate 10, a film material of the buffer layer 202 can be an inorganic material such as silicon oxide (SiOx), silicon nitride (SiNx), silicon oxynitride (SiON) or silicon nitride/silicon oxide laminated layer (SiNx/SiOx). The buffer layer 202 can prevent undesirable impurities or pollutants (such as moisture, oxygen, etc.) from diffusing from the substrate 10 into components that may be damaged by these impurities or pollutants, and can also provide a flat top surface. The gate insulating layer 204 is disposed on a side of the active layer 203 facing away from the substrate 10, and a material of the gate insulating layer 204 includes silicon oxide (SiOx), silicon nitride (SiNx) or a composite film formed by alternately stacking silicon oxide and silicon nitride. A material of the first metal layer 205 includes an alloy of one or more of molybdenum (Mo), aluminum (Al), copper (Cu) and titanium (Ti), which can be patterned to form a gate and a scanning line. A film material of the interlayer dielectric layer 206 can be an inorganic material, such as silicon oxide (SiOx), or silicon nitride/silicon oxide laminated layer (SiNx/SiOx). A material of the second metal layer 207 can be such as molybdenum (Mo), molybdenum/copper laminated layer (Mo/Cu) and molybdenum-titanium alloy/copper laminated layer (MoTi/Cu), and the second metal layer 207 can be patterned to form a source and a drain. The passivation layer 208 includes a first passivation layer 2081 and a second passivation layer 2082. A film material of the passivation layer 208 can be silicon oxide (SiOx), silicon nitride/silicon oxide laminated layer (SiNx/SiOx), or a laminated layer of silicon oxide (SiOx), nitrogen oxide (SiNx) and aluminum oxide (Al₂O₃).

Specifically, the top of the driving circuit layer 20 is a top of the black matrix layer 209, and the top of the black matrix layer 209 and the bottom of the substrate 10 form the first height h₁.

The protective layer 30 is disposed on the side of the driving circuit layer 20 facing away from the substrate 10, and includes multiple first protective layer structures 301, which are also called planarization (PLN) island, and each first protective layer structure 301 is arranged corresponding to each pad area A, and the first protective layer structures 301 are disposed on the passivation layer 208 in the pad areas A. The protective layer 30 is a planarization layer. The planarization layer is made of photoresist and is formed on the passivation layer 208 in an area (i.e., the pad area A, a baffle area B, a fan-out area or a GOA area C) outside the transistor and a storage capacitor area D of the driving backplane by coating. The protective layer 30 can provide a flat film surface for the display panel. The top of at least one first protective layer structure 301 and the bottom of the substrate 10 form the second height h₂, which is greater than the first height h₁ (i.e., h₂>h₁). By optimizing the graphic design of the protective layer 30, the effect of adjusting the film thickness is achieved, and the first protective layer structures 301 are processed in the pad areas, and the highest terrain is ensured at the first protective layer structures 301, so that the purpose of bearing external pressure through the protective layer pattern is achieved, and the metal circuits are prevented from being crushed by stress in the ACF bonding process or the stamping and pressing process, thereby improving the short circuit phenomenon and improving the product yield.

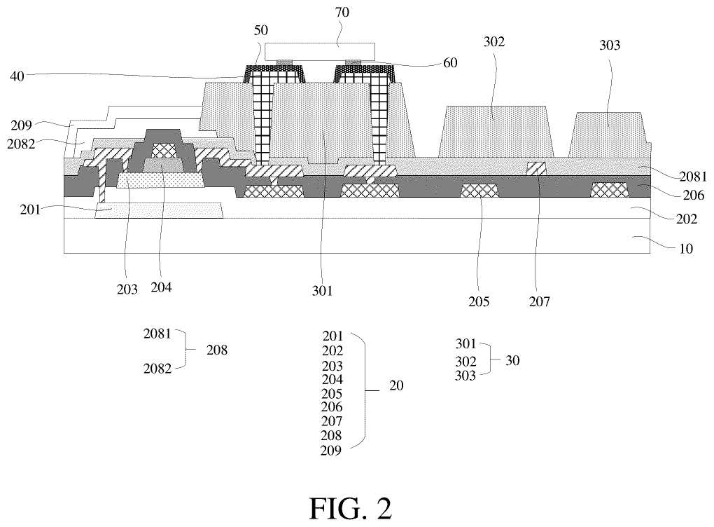

The pads 40 are formed on sides of the first protective layer structures 301 facing away from the driving circuit layer 20, and each pad 40 is connected with the driving circuit layer 20 through a via hole in each first protective layer structure 301. Specifically, a third metal layer is formed in via holes, which can be a sandwich structure formed by metal and metal oxide semiconductor, and the third metal layer can be patterned to form the pads 40. In addition, a conductive layer 50 is formed on the pads 40, and a material of the conductive layer 50 may include indium tin oxide (ITO). As shown in FIG. 2, FIG. 2 illustrates a schematic view of a cross section of the driving backplane provided by the embodiment of the present disclosure, conductive electrodes 60 are formed on the conductive layer 50, and a light-emitting pixel unit 70 is connected with the conductive layer 50 through the conductive electrodes 60, and the light-emitting pixel unit 70 is Micro-LED, which has intergenerational advantages in brightness, resolution, energy consumption, service life, response speed and thermal stability, and is an internationally recognized future display technology. In addition, each film layer is etched by a mask 90 to form patterned film layers as shown in FIG. 1.

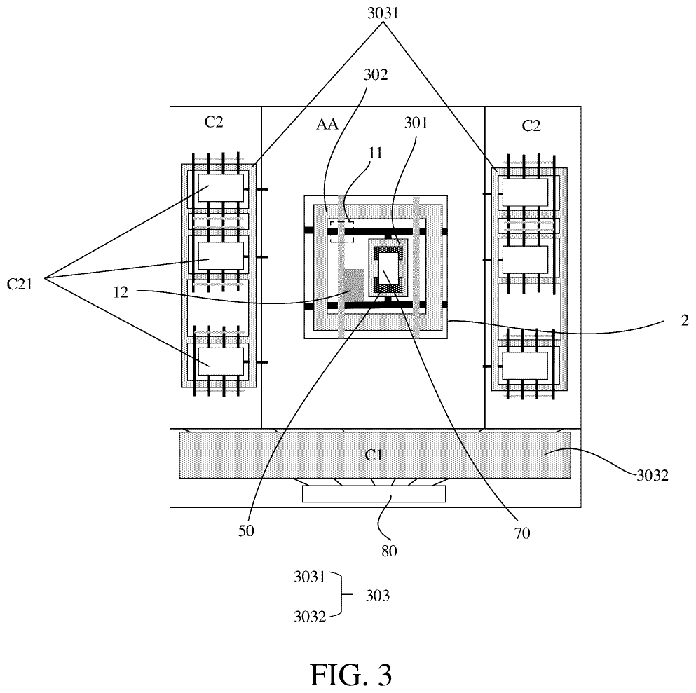

In an embodiment, the driving circuit layer 20 includes multiple signal lines, and orthogonal projections of at least two signal lines on the substrate 10 intersect to form an overlapping area, and an orthogonal projection of the first protective layer structure 301 on the substrate 10 does not overlap with the overlapping area. As shown in FIG. 3, FIG. 3 illustrates a top view of the driving backplane provided by the embodiment of the present disclosure, the orthogonal projections of at least two signal lines in the driving circuit layer 20 on the substrate 10 intersect to form an overlapping area 11, which is a metal jumper, and the first protective layer structure 301 is designed at a position avoiding the overlapping area 11 (metal jumper), so as to realize the purpose of bearing external pressure through the protective layer 30 and avoiding the stress of the metal circuit.

In an embodiment, the protective layer 30 includes at least one second protective layer structure 302, and the second protective layer structure 302 is arranged around the pad region A. A top of the second protective layer structure 302 and the bottom of the substrate 10 form a third height h₃, which is greater than the first height h₁ and less than the second height h₂. Specifically, the second protective layer structure 302 is also called a PLN wall. As shown in FIG. 1, the second protective layer structure 302 is arranged corresponding to the baffle area B. Combined with FIG. 3, the second protective layer structure 302 is arranged around the sub-pixel 2, and the second protective layer structure 302 is arranged around the pad area A, and can also be regarded as being arranged around the first protective layer structure 301. The third height h₃ is larger than the first height h₁ and smaller than the second height h₂, that is, h₁<h₃<h₂, so that the terrain height of the second protective layer structure 302 is second only to that of the first protective layer structure 301, and the transfer yield is ensured.

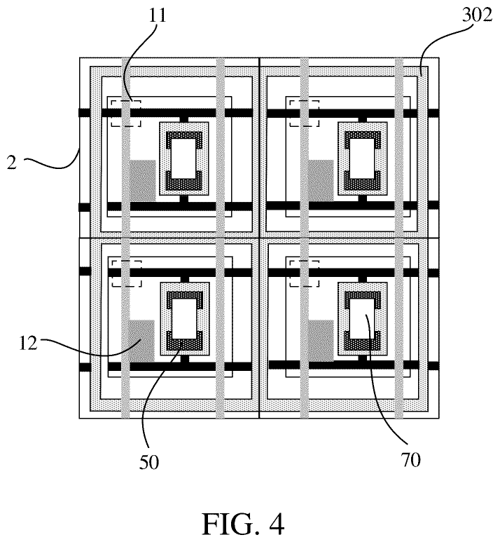

In an embodiment, multiple second protective layer structures 302 are formed in a grid shape. As shown in FIG. 4, FIG. 4 illustrates a schematic layout view of the second protective layer structures provided by the embodiment of the present disclosure, a schematic layout view of multiple sub-pixels 2 is illustrated, and the second protective layer structures 302 is arranged around the pad areas in sub-pixels, thus forming the grid shape, and the second protective layer structure 302 formed by each grid surrounds the pad area of the sub-pixel 2.

In an embodiment, the driving backplane further includes a display area AA and a GOA circuit area C2, the GOA circuit area C2 is disposed on at least one side of the display area AA, the driving circuit layer 20 includes multiple GOA driving units C21, the GOA circuit area C2 includes a first GOA circuit area and a second GOA circuit area, and the GOA driving units C21 are disposed in the first GOA circuit area. The protection layer 30 includes at least one third protection layer structure 3031, which is disposed in the second GOA circuit area. A top of the third protective layer structure 3031 and the bottom of the substrate 10 form a fourth height h₄, which is greater than the first height h₁ and less than the third height h₃. The first GOA circuit area refers to an area where the GOA driving units C21 are located, and the second GOA circuit area refers to an area where the GOA driving units C21 are not located. As shown in FIG. 3, the GOA circuit area C2 is disposed on two sides of the display area AA, and each GOA driving unit C21 includes a signal input end and a signal output end. Input signal lines are connected with the GOA driving unit through the signal input end to drive the GOA driving unit to work. The input signal lines are connected by cascaded lines, and the third protective layer structure 3031 is disposed in a blank position of the GOA circuit area C2, that is, in the second circuit area where the GOA driving units are not located, the fourth height ha is greater than the first height h₁ and less than the third height h₃, that is, h₁<h₄<h₃, so that the terrain height where the third protective layer structure 3031 is located is lower than that where the second protective layer structure 302 and the first protective layer structure 301 are located, ensuring the highest terrain where the first protective layer structure 301 is located, thus ensuring the transfer yield.

In an embodiment, the third protective layer structure 3031 is disposed around the GOA driving units C21.

In an embodiment, the driving backplane further includes a fan-out area C1, and the driving circuit layer 20 further include a fan-out line, the fan-out line is disposed in the fan-out area C1. The protective layer 30 includes a fourth protective layer structure 3032 disposed in the fan-out area C1. A top of the fourth protective layer structure 3032 and the bottom of the substrate 10 form a fifth height h₅, which is greater than the first height h₁ and less than the third height h₃. Specifically, the fourth protective layer structure 3032 covers the fan-out area C1 throughout its entire layer, the fifth height h₅ is greater than the first height h₁ and less than the third height h₃, that is, h₁<h₅<h₃. Here, the relationship between the fourth height h₄ of the third protective layer structure 3031 and the fifth height h₅ of the fourth protective layer structure 3032 is not limited, as long as the terrain where the first protective layer structure 301 is located is the highest and the terrain where the second protective layer structure is located is the second.

In an embodiment, the fourth protective layer structure 3032 covers the fan-out area C1 in its entire structure. It should be noted that the third protective layer structure 3031 and the fourth protective layer structure 3032 are collectively referred to as a third protective layer structure group 303.

In an embodiment, the material of the protective layer 30 is an organic photoresist, and a thickness of the protective layer made of the organic photoresist is not limited by the CVD film forming machine and the dry etching machine.

The present disclosure further provides a display panel, which includes a driving backplane and a light source, the driving backplane is the driving backplane described in any of the above embodiments. The display panel is a Micro-LED display panel. The display panel of the present disclosure does not need to increase additional processes and materials, and does not need to increase the processing cycle. It is only optimized by the graphic design of the protective layer. Through the arrangement of the first protective layer structures, the position of each pad is guaranteed to be at the highest terrain of the whole panel, and the transfer yield is guaranteed. The design of the second protective layer structure and the third protective layer structure group ensures that the panel circuits are not pressed during the ACF bonding process and the stamping and pressing process, thereby avoiding the short circuit phenomenon of the display panel and improving the product yield.

According to the above embodiments:

The present disclosure provides a driving backplane and a display panel. The driving backplane includes multiple pad areas and multiple non-pad areas, the driving backplane includes a substrate, a driving circuit layer, a protective layer and multiple pads, the driving circuit layer is disposed on a side of the substrate, a top of the driving circuit layer and a bottom of the substrate form a first height, the protective layer is disposed on a side of the driving circuit layer facing away from the substrate, the protective layer includes multiple first protective layer structures, the first protective layer structures are respectively disposed corresponding to the pad areas, the pads are formed on sides of the first protective layer structures facing away from the driving circuit layer, each pad is connected with the driving circuit layer through a via hole in each first protective layer structure, a top of at least one first protective layer structure forms a second height with the bottom of the substrate, and the second height is greater than the first height. The present disclosure optimizes the graphic design of the protective layer to achieve the effect of adjusting the thickness of film layers, the transfer yield is guaranteed by ensuring the highest terrain at the first protective layer structure, and the panel circuits are not pressed during the ACF bonding process and the stamping and pressurizing process, thereby avoiding the occurrence of backplate short circuits and greatly improving the product yield.

In the above-mentioned embodiments, the description of each embodiment has its own emphasis. For the parts not detailed in one embodiment, please refer to the relevant descriptions of other embodiments.

The above provides a detailed introduction to the driving backplane and the display panel provided by the embodiments of the present disclosure. Specific examples are applied in this article to explain the principles and implementation methods of the present disclosure. The explanations of the above embodiments are only used to help understand the technical solutions and their core ideas of the present disclosure. Those skilled in the art should understand that they can still modify the technical solutions recorded in the aforementioned embodiments, or equivalently replace some of the technical features; and these modifications or replacements do not separate the essence of the corresponding technical solutions from the scope of the technical solutions of the various embodiments of the present disclosure.

What is claimed is:

1. A driving backplane, comprising: a plurality of pad areas and a plurality of non-pad areas; wherein the driving backplane comprises:
a substrate;
a driving circuit layer, disposed on a side of the substrate; wherein a top of the driving circuit layer forms a first height with a bottom of the substrate;
a protective layer, disposed on a side of the driving circuit layer facing away from the substrate; wherein the protective layer comprises a plurality of first protective layer structures, and each of the first protective layer structures is disposed corresponding to each of the plurality of pad areas; and
a plurality of pads, formed on sides of the first protective layer structures facing away from the driving circuit layer; wherein each of the plurality of pads is connected with the driving circuit layer through a via hole in each of the first protective layer structures;
wherein a top of at least one of the first protective layer structures forms a second height with the bottom of the substrate, and the second height is greater than the first height.

2. The driving backplane according to claim 1, wherein the driving circuit layer comprise a plurality of signal lines, and orthogonal projections of at least two of the signal lines on the substrate intersect to form an overlapping area; and an orthogonal projection of each of the first protective layer structures on the substrate does not overlap with the overlapping area.

3. The driving backplane according to claim 1, wherein the protective layer comprises at least one second protective layer structure, disposed around the pad area; and a top of the second protective layer structure forms a third height with the bottom of the substrate, and the third height is greater than the first height and less than the second height.

4. The driving backplane according to claim 3, wherein the at least one second protective layer structure is a plurality of second protective layer structures, and the protective layer structures form a grid shape.

5. The driving backplane according to claim 3, wherein the driving backplane further comprises a display area and a gate on array (GOA) circuit area, the GOA circuit area is disposed on at least one side of the display area, the driving circuit layer comprises a plurality of GOA driving units, the GOA circuit area comprises a first GOA circuit area and a second GOA circuit area, and the GOA driving units are disposed in the first GOA circuit area; the protective layer comprises at least one third protective layer structure disposed in the second GOA circuit area; and a top of the third protective layer structure forms a fourth height with the bottom of the substrate, and the fourth height is greater than the first height and less than the third height.

6. The driving backplane according to claim 5, wherein the third protective layer structure is disposed around the GOA driving units.

7. The driving backplane according to claim 5, wherein the driving backplane further comprises a fan-out area, and the driving circuit layer further comprises a fan-out line disposed in the fan-out area; the protective layer comprises a fourth protective layer structure disposed in the fan-out area; and a top of the fourth protective layer structure forms a fifth height with the bottom of the substrate, and the fifth height is greater than the first height and less than the third height.

8. The driving backplane according to claim 7, wherein the fourth protective layer structure covers the fan-out area throughout its entire layer.

9. The driving backplane according to claim 1, wherein a material of the protective layer is an organic photoresist.

10. A display panel, comprising a driving backplane and a light source; wherein the driving backplane comprises:
a substrate;
a driving circuit layer, disposed on a side of the substrate; wherein a top of the driving circuit layer forms a first height with a bottom of the substrate;
a protective layer, disposed on a side of the driving circuit layer facing away from the substrate; wherein the protective layer comprises a plurality of first protective layer structures, and each of the first protective layer structures is disposed corresponding to each of the plurality of pad areas; and
a plurality of pads, formed on sides of the first protective layer structures facing away from the driving circuit layer; wherein each of the plurality of pads is connected with the driving circuit layer through a via hole in each of the first protective layer structures;
wherein a top of at least one of the first protective layer structures forms a second height with the bottom of the substrate, and the second height is greater than the first height.

11. The display panel according to claim 10, wherein the driving circuit layer comprise a plurality of signal lines, and orthogonal projections of at least two of the signal lines on the substrate intersect to form an overlapping area; and an orthogonal projection of each of the first protective layer structures on the substrate does not overlap with the overlapping area.

12. The display panel according to claim 10, wherein the protective layer comprises at least one second protective layer structure, disposed around the pad area; and a top of the second protective layer structure forms a third height with the bottom of the substrate, and the third height is greater than the first height and less than the second height.

13. The display panel according to claim 12, wherein the at least one second protective layer structure is a plurality of second protective layer structures, and the protective layer structures form a grid shape.

14. The display panel according to claim 12, wherein the driving backplane further comprises a display area and a gate on array (GOA) circuit area, the GOA circuit area is disposed on at least one side of the display area, the driving circuit layer comprises a plurality of GOA driving units, the GOA circuit area comprises a first GOA circuit area and a second GOA circuit area, and the GOA driving units are disposed in the first GOA circuit area; the protective layer comprises at least one third protective layer structure disposed in the second GOA circuit area; and a top of the third protective layer structure forms a fourth height with the bottom of the substrate, and the fourth height is greater than the first height and less than the third height.

15. The display panel according to claim 14, wherein the third protective layer structure is disposed around the GOA driving units.

16. The display panel according to claim 14, wherein the driving backplane further comprises a fan-out area, and the driving circuit layer further comprises a fan-out line disposed in the fan-out area; the protective layer comprises a fourth protective layer structure disposed in the fan-out area; and a top of the fourth protective layer structure forms a fifth height with the bottom of the substrate, and the fifth height is greater than the first height and less than the third height.

17. The display panel according to claim 16, wherein the fourth protective layer structure covers the fan-out area throughout its entire layer.

18. The display panel according to claim 10, wherein a material of the protective layer is an organic photoresist.

19. A driving backplane, comprising: a plurality of pad areas and a plurality of non-pad areas; wherein the driving backplane comprises:
a substrate;
a driving circuit layer, disposed on a side of the substrate; wherein a top of the driving circuit layer forms a first height with a bottom of the substrate;
a protective layer, disposed on a side of the driving circuit layer facing away from the substrate; wherein the protective layer comprises a plurality of first protective layer structures, and each of the first protective layer structures is disposed corresponding to each of the plurality of pad areas; and
a plurality of pads, formed on sides of the first protective layer structures facing away from the driving circuit layer; wherein each of the plurality of pads is connected with the driving circuit layer through a via hole in each of the first protective layer structures;
wherein a top of at least one of the first protective layer structures forms a second height with the bottom of the substrate, and the second height is greater than the first height;
wherein the driving circuit layer comprise a plurality of signal lines, and orthogonal projections of at least two of the signal lines on the substrate intersect to form an overlapping area; and an orthogonal projection of each of the first protective layer structures on the substrate does not overlap with the overlapping area;
wherein the protective layer comprises at least one second protective layer structure, disposed around the pad area; and a top of the second protective layer structure forms a third height with the bottom of the substrate, and the third height is greater than the first height and less than the second height.

20. The driving backplane according to claim 19, wherein the at least one second protective layer structure is a plurality of second protective layer structures, and the protective layer structures form a grid shape.
